(19) United States
(12) Patent Application Publication
(10) Pub. No.: US 2025/0226293 A1
(43) Pub. Date: Jul. 10, 2025

(54) Embedded Power Semiconductor Package with Sidewall Contacts

(71) Applicant: Infineon Technologies AG, Neubiberg (DE)

(72) Inventors: Eung San Cho, Torrance, CA (US); Thomas Gebhard, Villach (AT); Tomasz Naeve, Finkenstein (AT); Milad Mostofizadeh, München (DE); Tyrone Jon Soller, Graz (AT); Yang Yoon Lee, Ipoh (MY)

(21) Appl. No.: 18/403,854

(22) Filed: Jan. 4, 2024

(51) Int. Cl. H01L 23/495; H01L 23/00; H01L 23/31

(52) U.S. Cl. CPC H01L 23/49524; H01L 23/3121; H01L 24/96; H01L 2224/96; H01L 2924/1811

(57) ABSTRACT

A method of forming a semiconductor package includes providing a lead frame including a metal frame at least partially surrounding a central opening and a plurality of tie bars connected between the metal frame and an adjacent stabilizing metal section, arranging the lead frame on a temporary carrier, arranging a semiconductor die on the temporary carrier within the central opening, forming a dielectric material that fills the central opening and encapsulates the semiconductor die, forming a first recess in the dielectric material above the semiconductor die so as to expose a first surface of the semiconductor die, electrically connecting terminals of the semiconductor die with the metal frame, and forming exposed outer contacts of the semiconductor package from the tie bars.

### BACKGROUND

Semiconductor power device packages are used in many applications such as automotive and industrial applications. A semiconductor power device package may include one or more discrete power semiconductor devices that are rated to control large voltages and/or currents, e.g., MOSFETs (metal oxide semiconductor field effect transistors), IGBTs (insulated gate bipolar transistors), diodes, etc., and in some cases may include driver devices that are configured to control the discrete power semiconductor devices. Different types of package configurations are used for power applications. One type of package configuration used in power applications is an embedded package. An embedded package embeds a die within a PCB-like structure that both encapsulates the die and provides electrical interconnect with externally accessible bond pads. It is desirable to improve performance, cost and manufacturability of embedded packages.

### SUMMARY

A method of forming a semiconductor package is disclosed. According to an embodiment, the method comprises providing a lead frame comprising a metal frame at least partially surrounding a central opening and a plurality of tie bars connected between the metal frame and an adjacent stabilizing metal section; arranging the lead frame on a temporary carrier; arranging a semiconductor die on the temporary carrier within the central opening; forming a dielectric material that fills the central opening and encapsulates the semiconductor die; forming a first recess in the dielectric material above the semiconductor die so as to expose a first surface of the semiconductor die; electrically connecting terminals of the semiconductor die with the metal frame; and forming exposed outer contacts of the semiconductor package from the tie bars.

A semiconductor package is disclosed. According to an embodiment, the semiconductor package comprises a metal frame that forms an at least partially enclosed shape around a central opening; severed tie bars connected with the metal frame; a semiconductor die arranged within the central opening; and a dielectric material that fills the central opening and encapsulates the semiconductor die, wherein terminals of the semiconductor die are electrically connected with the metal frame, and wherein the semiconductor package comprises exposed outer contacts of the semiconductor package formed from the severed tie bars.

### BRIEF DESCRIPTION OF THE FIGURES

The elements of the drawings are not necessarily to scale relative to each other. Like reference numerals designate corresponding similar parts. The features of the various illustrated embodiments can be combined unless they exclude each other. Embodiments are depicted in the drawings and are detailed in the description which follows.

FIG. 1, which includes FIGS. 1A and 1B, illustrates a power semiconductor package, according to an embodiment. FIG. 1A illustrates a cross-sectional perspective of the power semiconductor package and FIG. 1B illustrates a side-view perspective of the power semiconductor package.

FIG. 2, which includes FIGS. 2A and 2B, illustrates a power semiconductor package, according to an embodiment. FIG. 2A illustrates a cross-sectional perspective of the power semiconductor package and FIG. 2B illustrates a side-view perspective of the power semiconductor package.

FIG. 3, which includes FIGS. 3A and 3B, illustrates a power semiconductor package, according to an embodiment. FIG. 3A illustrates a cross-sectional perspective of the power semiconductor package and FIG. 3B illustrates a side-view perspective of the power semiconductor package.

FIG. 4 illustrates a lead frame that is used to form a power semiconductor package, according to an embodiment.

FIG. 5, which includes FIGS. 5A, 5B, 50, 5D, 5E, 5F, 5G, 5H, and 5I, illustrates selected method steps in a method of forming a semiconductor package, according to an embodiment.

FIG. 6 illustrates a power semiconductor package from a cross-sectional perspective, according to an embodiment.

### DETAILED DESCRIPTION

Embodiments of a power semiconductor package with an advantageous contact configuration and corresponding methods of forming the power semiconductor package are disclosed herein. The power semiconductor package comprises one or more semiconductor dies that are embedded within the package and connected with externally accessible bond pads. The power semiconductor package is formed by providing a metal frame that at least partially surrounds a central opening. One or more semiconductor dies are arranged within the central opening and encapsulated by a dielectric material. The metal frame provides a cost-effective solution for forming an embedded package structure. The metal frame can be configured as a vertical through-via structure that provides an electrical connection between a rear surface terminal of the semiconductor die and a bond pad disposed at a lower interfacing side of the semiconductor package. The metal frame is provided from a lead frame structure with tie bars connected between the metal frame and an adjacent stabilizing structure. Advantageously, the tie bars that mechanically support the metal frame during package assembly are incorporated into the final package structure and form exposed outer contacts of the power semiconductor package. The method advantageously lowers processing expense by eliminating the need to remove or otherwise insulate the tie bars from the exterior environment. Moreover, the exposed surfaces of the tie bars can advantageously form so-called LTI (lead tip inspection) features.

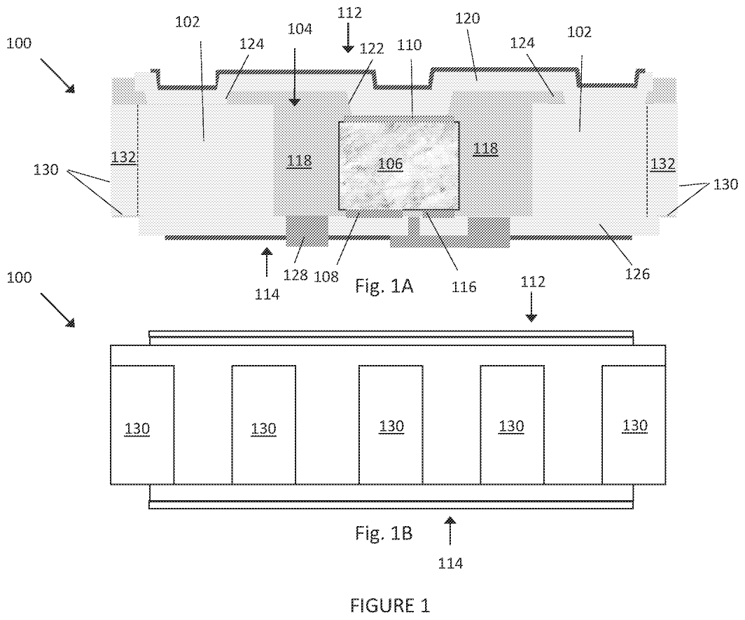

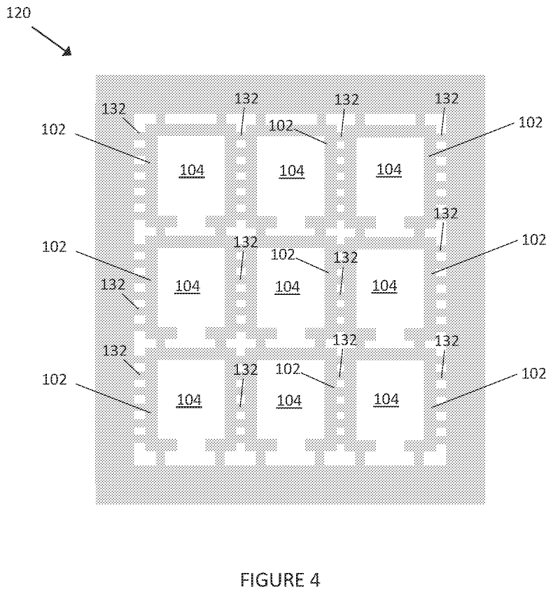

Referring to FIG. 1, a semiconductor package 100 comprises a metal frame 102. The metal frame 102 may comprise an electrically conductive metal such as copper, aluminum, nickel, silver, palladium, gold, etc., and alloys thereof. The metal frame 102 may comprise a comprise a core metal region and one or more plating layers that are used for protection, adhesion, anti-corrosion, etc. formed on the core metal region. The metal frame 102 forms an at least partially enclosed shape around a central opening 104. From a plan-view perspective of the metal frame 102, the metal frame 102 defines a shape of the central opening 104. The description that the metal frame 102 forms an at least partially enclosed shape refers to the fact that there may be one or more interruptions in the continuity of the metal frame 102 such that the central opening 104 is not entirely enclosed by the metal frame 102. For example, as shown in FIG. 4, the metal frame 102 forms a partially enclosed shape around the central opening 104, with one interruption at one side of the metal frame 102. In other embodiments, there may be multiple interruptions in the metal frame 102. In still other embodiments, there may be no interruptions in the metal frame 102, i.e., the metal frame 102 forms a completely enclosed shape around the central opening 104. Provided that the metal frame 102 borders at least 50% of the of the overall diameter of the central opening 104, with the remaining diameter of the central opening 104 being defined by intersecting planes that interior edge sides of the metal frame 102 extend along, the metal frame 102 forms a partially enclosed shape around a central opening 104 within the meaning of the instant specification.

Referring again to FIG. 1, the semiconductor package 100 comprises a semiconductor die 106 arranged within the central opening 104 of the metal frame 102. Generally speaking, the semiconductor die 106 may be configured as any type of device. According to an embodiment, the semiconductor die 106 is configured as a power device, i.e., a device that is rated to accommodate voltages 100 V (volts), 600 V, 1200V or more and/or rated to accommodate currents of at least 1 A (amperes), 10 A, 50 A, 100 A or more. Examples of these power devices include MOSFETs (metal-oxide-semiconductor field-effect transistors), HEMTs (high-electron mobility transistors), IGBTs (insulated-gate bipolar transistor), JFETs (junction filed-effect transistors), diodes. The semiconductor die 106 may be formed in any device technology and may include IV semiconductor materials, e.g., silicon, silicon germanium, silicon carbide, etc., and/or type III-V semiconductor materials, e.g., gallium nitride, gallium arsenide, etc. According to an embodiment, the semiconductor die 106 is configured as a vertical device that is configured to conduct a vertical current between a first load terminal 108 and a second load terminal 110. The first and second load terminals 108, 110 are the voltage blocking terminals of the device. For example, the first and second load terminals 108, 110 may respectively correspond to the drain and source terminals (or vice-versa) of a MOSFET, may correspond to the collector and emitter terminals (or vice-versa) of an IGBT, and so forth. As shown, the semiconductor die 106 comprises a first surface that faces an upper side 112 of the semiconductor package 100 and a second surface that faces a lower side 114 of the semiconductor package 100, i.e., a side of the semiconductor package 100 that mates with an external carrier, such as a PCB (printed circuit board). The first surface of the depicted semiconductor die 106 corresponds to a rear surface of the semiconductor die 106 that comprises the second load terminal 110, and the second surface of the depicted semiconductor die 106 corresponds to the main surface of the semiconductor die 106 that comprises the first load terminal 108 and a gate terminal 116. The gate terminal 116 is configured to control a conductive connection between the first and second load terminals 108, 110 in a commonly known manner.

The semiconductor package 100 may be configured to form a power switching device that is part of a power conversion circuit. For example, the semiconductor package 100 may be configured as the high-side switch or the low-side switch of a half bridge circuit. A half-bridge circuit refers to one type of circuit topology that is used in a power conversion circuit, such as a DC-to-DC converter, DC-to-AC converter, etc. Instead of the single die configuration as shown, the semiconductor package 100 may have a multi-die configuration. For example, the semiconductor package 100 may comprise two power semiconductor device dies that form the high-side switch and the low-side switch, respectively, of a half bridge circuit. These semiconductor dies may be arranged within the opening or within different openings 104 of a metal frame. Separately or in combination, the semiconductor package 100 may comprise additional semiconductor dies that are not configured as power dies, e.g., low voltage and or logic devices. For example, the semiconductor package 100 may comprise a driver die that is arranged within another opening of the metal fame 102 and encapsulated according to the technique to be described below, wherein the driver die is configured to control a switching operation of the semiconductor dies that are configured as power switching devices.

The semiconductor package 100 comprises a dielectric material 118 that fills the central opening 104 and encapsulates the semiconductor die 106. The dielectric material 118 may comprise a resin material such as bismaleimide trazine (BT) resin, a prepreg material such as FR-4, FR-5, CEM-4, or other types of encapsulation material. The dielectric material 118 may be formed as part of a lamination process whereby multiple constituent laminate layers are stacked on top of one another. One example of a lamination process is described below.

According to an embodiment, at least one of the terminals of the semiconductor die 106 is electrically connected with the metal frame 102. In this way, the metal frame 102 can serve as a through-via structure that provides electrical connectivity between the rear surface of the semiconductor die 102 the lower side 114 of the semiconductor package 100. In the depicted embodiment, the second load terminal 110 of the semiconductor die 106 is electrically connected to the metal frame 102 and is thus electrically accessible at the lower side 114 of the semiconductor package 100. The semiconductor package 100 comprises a first metallization layer 120 that is formed at the upper side 112 of the semiconductor package 100 and forms the electrical connection between the second load terminal 110 and the metal frame 102. The electrical connection is made possible by the formation of recesses in the dielectric material 118. Specifically, a first recess 122 is formed in the dielectric material 118 over the rear surface of the semiconductor die 106. The second load terminal 110 of the semiconductor die 106 is exposed by the first recess 122. Additionally, second recesses 124 are formed in the dielectric material 118 over the metal frame 102. Each of the second recesses 122 expose an upper surface of the metal frame 102, thereby allowing for a metal connection thereto. The first metallization layer 120 is conformally deposited on the dielectric material 118, thereby forming the electrical connection with the second load terminal 110 and the metal frame 102. The semiconductor package 100 additionally comprises a second metallization layer 126 formed at the lower side 114 of the semiconductor package 100. The second metallization layer 126 is formed directly on the first load terminal 108, the gate terminal 116 and the metal frame 102 and forms separate and externally accessible bond pads of the semiconductor package 100. These bond pads may be mated with an external carrier such as a PCB or power electronics substrate, e.g., AMB (active metal brazed) substrate, IMS (insulated metal substrate), etc., e.g., by soldering the bond pads to corresponding metal pads. The semiconductor package 100 additionally comprises a solder mask 128 at the lower interfacing side of the semiconductor package 100 to electrically isolate each of the bond pads and facilitate direct board mounting of the semiconductor package 100. The solder mask 128 may comprise a solder resist material such as a lacquer, epoxy, liquid photoimageable solder mask 128, dry-film photoimageable solder mask 128, etc.

The semiconductor package 100 is configured with exposed outer contacts 130 that are disposed at the outer edge side of the semiconductor package 100. The exposed outer contacts 130 extend transversely to the lower side 114 of the semiconductor package 100. The exposed outer contacts 130 can serve as LTI (lead tip inspection) features. LTI features allow for optical inspection of a solder joint when the semiconductor package 100 is mounted on an external apparatus, such as a printed circuit board, by revealing the metal-solder interface at the outer edge side of the package. Separately or in combination, the exposed outer contacts 130 may provide additional electrical contact points that are available for electrical contact to the external environment when the semiconductor package 100 is mounted on an external carrier.

According to an embodiment, the outer contacts 130 are formed by tie bars 132. The tie bars 132 are metal structures used to mechanically support the metal frame 102 during package construction and before encapsulation. As shown in FIG. 4, the semiconductor package 100 may be produced from a lead frame 200 which comprises a plurality of the metal frames 102, each defining one of the central openings 104. A plurality of tie bars 132 extends between each one of the metal frames 102 and an adjacent stabilizing metal section of the lead frame 200.

The embodiments disclosed herein configure the semiconductor package 100 such that at least portions of the tie bars 132 remain intact, i.e., the tie bars 132 are not trimmed or otherwise removed completely. The remaining portions of the tie bars 132 are exposed at the at the outer edge side of the semiconductor package 100, thereby forming the exposed outer contacts 130 that extend transversely to the lower interfacing side of the semiconductor package 100. According to an embodiment, the exposed outer contacts 130 comprise sidewall surfaces of the tie bars 132. These sidewall surfaces may correspond to surfaces of the tie bars 132 that are severed. e.g., etching, laser ablation, mechanical drilling, etc., during a package singulation process, as will be described in further detail below. Alternatively, these sidewall surfaces may correspond to surfaces of the tie bars 132 that are etched prior to package singulation, as will be described in further detail below. As shown in FIG. 1B, the outer edge sides of the semiconductor package 100 may comprise a plurality of the outer contacts 130 provided by individual tie bars 132, wherein each one of these individual tie bars 132 structures forms a connection with the internally disposed metal frame 102.

According to an embodiment, the exposed outer contacts 130 additionally comprise lower surfaces of the tie bars 132 that intersect the sidewall surfaces of the tie bars 132. For example, as shown in FIG. 1A, lower surfaces of the tie bars 132 extend to the outer edge side of the semiconductor package 100 and intersect with a sidewall surface of the tie bar 132 that extends transversely to the lower side 114 of the semiconductor package 100. In this way, the tie bars 132 may form a complete LTI feature of the semiconductor package 100, allowing for inspection at the corner of the package terminal.

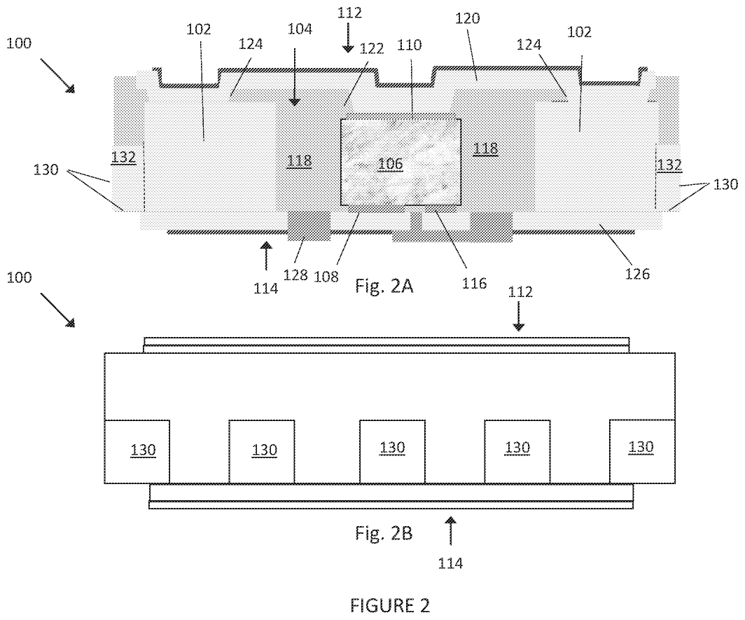

Referring to FIG. 2, a semiconductor package 100 is shown, according to an embodiment. The semiconductor package 100 is similar to that of FIG. 1, except that the tie bars 132 are thinner than the metal frame 102 that encloses the central opening 104. In this case, the lead frame 200 used to form the semiconductor package 100 has been processed to remove metal from the tie bar portions of the lead frame 200. As a result, the exposed outer contacts 130 of the semiconductor package 100 formed by the tie bars 132 have less vertical extension, e.g., as shown in FIG. 2B. The dielectric material 118 is formed above the reduced thickness tie bars 132, thereby maintaining the shape of the semiconductor package 100.

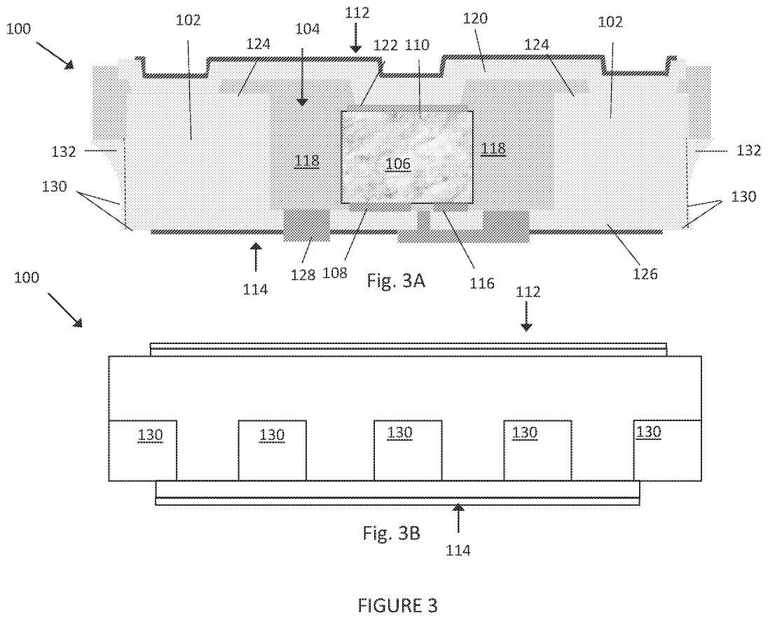

Referring to FIG. 3, a semiconductor package 100 is shown, according to an embodiment. The semiconductor package 100 is similar to that of FIG. 2, except that the tie bars 132 have been processed by an etching process prior to a package singulation step. As a result, the outer contacts 130 of the semiconductor package 100 formed by the tie bars 132 correspond to the etched surfaces of the tie bars 132. As shown, these etched surfaces may have a curved shape and create an indentation at the lower outer corner of the semiconductor etched surfaces. This curved shape of the exposed outer contacts 130 may enhance solderability and/or lead tip inspection.

Referring to FIG. 4, a lead frame 200 that is used to form a plurality of the semiconductor packages 100 is shown, according to an embodiment. The lead frame 200 may be provided from a sheet metal of electrically conductive metals such as copper, aluminum, nickel, silver, palladium, gold, etc., and alloys thereof. The lead frame 200 may comprise a comprise a core metal region and one or more plating layers on the core metal region that are used for protection, adhesion, anti-corrosion, etc. The geometry of the lead frame 200 may be created by metal processing techniques, e.g., stamping, punching, cutting, etc. As shown, the lead frame 200 comprises a plurality of the metal frames 102, each defining one of the central openings 104. Each of the metal frames 102 are physically connected with an adjacent stabilizing metal section by the tie bars 132. The adjacent stabilizing metal section may refer to an outer peripheral structure of the lead frame 200 that is adjacent to the outermost ones of the metal frames 102. The adjacent stabilizing metal section may also refer to adjacent ones of the metal frames 102 that are immediately adjacent to one another. The tie bars 132 maintain the structural integrity of the lead frame 200 during processing and before package singulation.

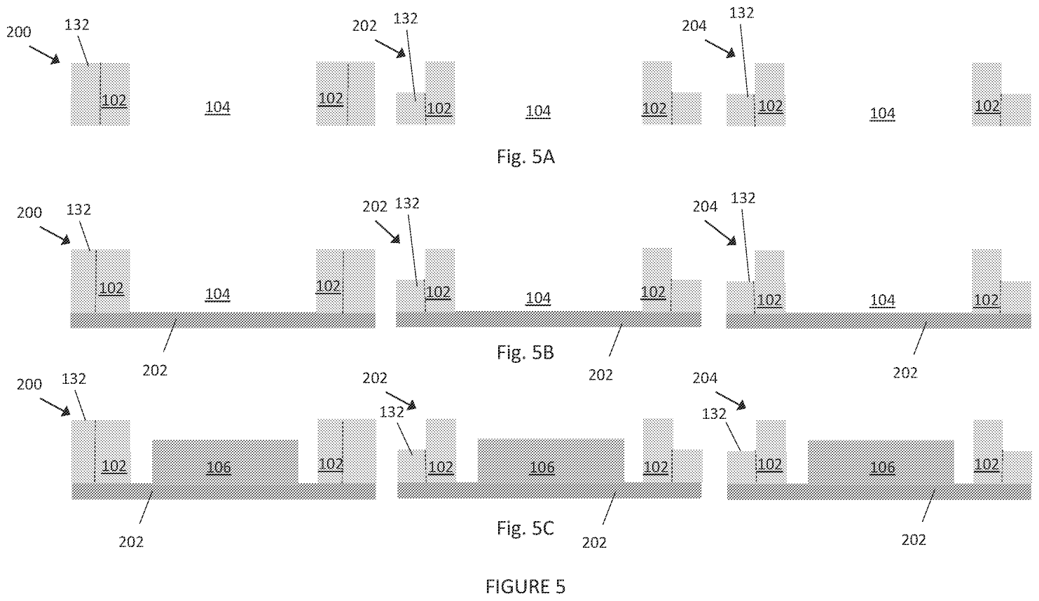

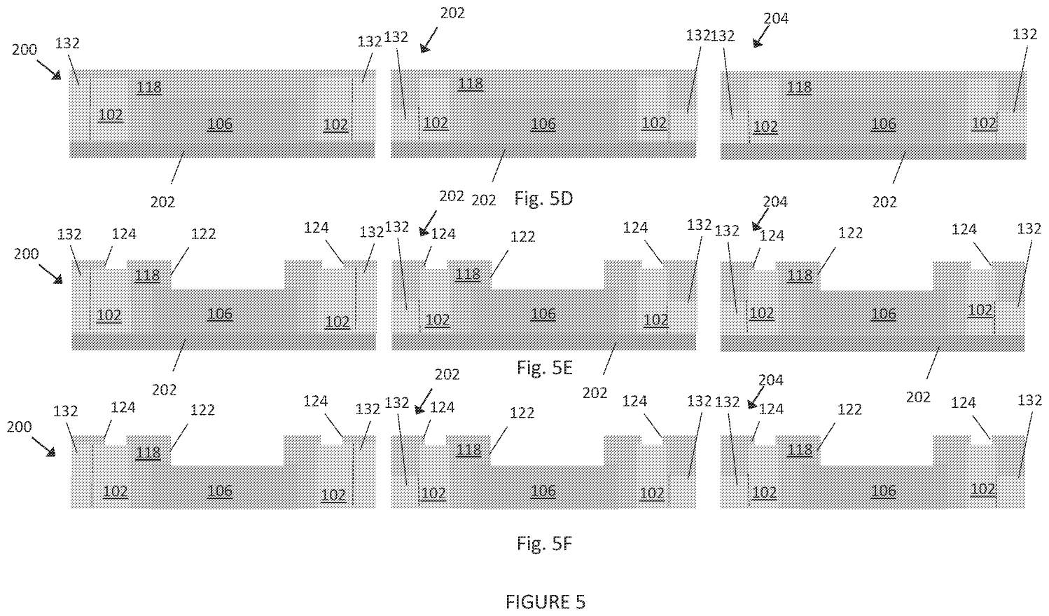

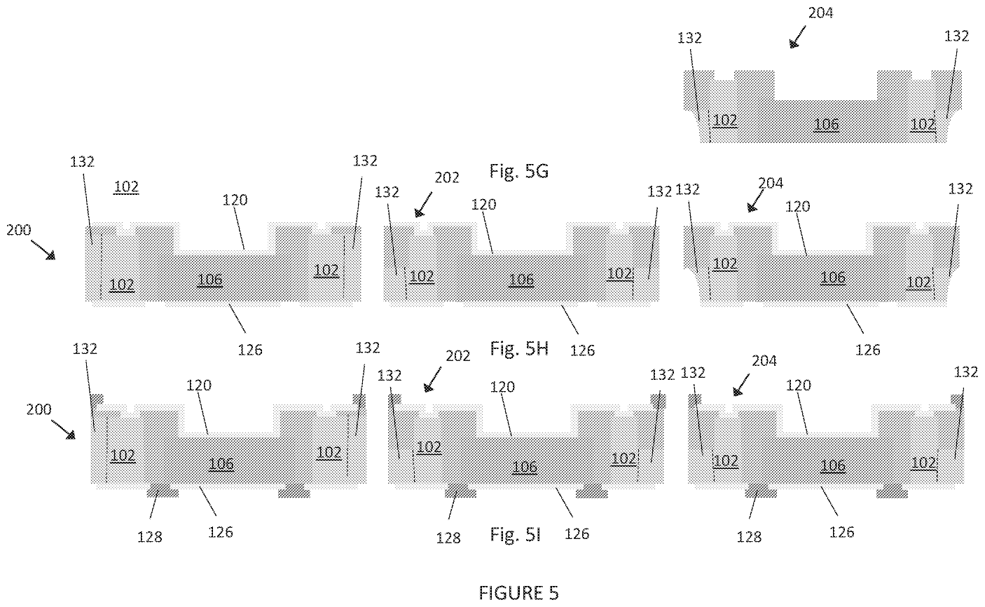

Referring to FIG. 5, selected method steps for forming semiconductor packages 100 according to various embodiments are shown. Each of the figures show a first package assembly 200 on the left side of the figure, a second package assembly 202 in the center of the figure, and a third package assembly 204 on the right side of the figure. The method steps performed on the first package assembly 200 may be used to produce the semiconductor package 100 described with reference to FIG. 1. The method steps performed on the second package assembly 202 may be used to produce the semiconductor package 100 described with reference to FIG. 2. The method steps performed on the third package assembly 204 may be used to produce the semiconductor package 100 described with reference to FIG. 3.

Referring to FIG. 5A, a lead frame 200 is provided. The lead frame 200 can correspond to the lead frame 200 described with reference to FIG. 4. The first package assembly 200, the second package assembly 202 and the third package assembly 204 each depict a cross-section of a package site from the lead frame 200 with one of the metal frames 102 and the corresponding tie bars 132 connected with the metal frame 102. In the case of the first package assembly 200, the lead frame 200 is provided with the tie bars 132 and the metal frame 102 having the same thickness. In the case of the second package assembly 202 and the third package assembly 204, the lead frame 200 is provided such that the tie bars 132 have a reduced thickness in comparison to the metal frame 102. For example, a half-etching step may be performed on the lead frame 200. Half etching refers to a technique whereby a metal structure such as a lead frame is partially etched to selectively reduce the thickness of the structure in certain features. In general, the half-etching step may reduce the thickness of the lead frame 200 by at least 30%, at least 40%, at least 50%, at least 60%, at least 70%, etc. Accordingly, the thickness of the tie bars 132 may be at least 70%, at least 60%, at least 50%, at least 40%, at least 30%, etc. of the metal frame 102.

Referring to FIG. 5B, the lead frame 200 is placed on a temporary carrier 202. Generally speaking, the temporary carrier 202 can be any planar surface that is suitable for handling, and transfer of electronic components through various semiconductor processing tools. In one example, the temporary carrier 202 includes a thermal release tape.

Referring to FIG. 5C, a semiconductor die 106 is arranged on the temporary carrier 202. The semiconductor die 106 is placed within the central opening 104 of the metal frame 102 and is spaced apart from the metal frame 102 in every direction. The semiconductor die 106 can have any of the device configurations as described above.

Referring to FIG. 5D, a dielectric material 118 is formed to fill the central opening 104 of the metal and encapsulate the semiconductor die 106. As shown, the dielectric material 118 is formed to fill the lateral space between the semiconductor die 106 and the metal frame 102. Additionally, the dielectric material 118 is initially formed to completely cover the semiconductor die 106 and the metal frame 102. According to an embodiment, the dielectric material 118 is formed by a lamination technique. Lamination refers to a process whereby multiple constituent layers of dielectric material 118 are formed successively. For example, the lamination technique may comprise forming a region of resin such as bismaleimide trazine (BT) resin that secures central opening 104 that encapsulates and secures the semiconductor die 106 within the metal frame 102. One or more additional constituent layers of dielectric material 118 may be formed on top of this resin. These additional constituent layers may comprise a prepreg material such as FR-4, FR-5, CEM-4, etc.

Referring to FIG. 5E, recesses are formed in the dielectric material 118. Specifically, the first recess 122 is formed in the dielectric material 118 over the rear surface of the semiconductor die 106, thereby exposing the second load terminal 110 (not shown in FIG. 5) of the semiconductor die 106. Additionally, the second recesses 124 are formed in the dielectric material 118 over the metal frame 102, thereby exposing the upper surface of the metal frame 102. In general, the first and second recesses 122, 124 may be formed by a variety of techniques, e.g., etching, laser ablation, mechanical drilling, etc.

Referring to FIG. 5F, the temporary carrier 202 is removed from the lower sides of the package assembly. Due to the hardened dielectric material 118, each semiconductor assembly may remain intact in further processing steps without the need for the temporary carrier 202. In the case that the temporary carrier 202 is a thermal release tape, this removal may involve heating the assembly to the appropriate temperature and peeling the thermal release tape away from the assembly.

Referring to FIG. 5G, an additional etching process is performed only on the third package assembly 204 shown on the right side of the figures. Thus, the additional etching process of FIG. 5G may be omitted from the process sequences performed on the first and second package assemblies 200, 202. The additional etching process removes material from the lead frame 200 in the vicinity of the tie bars 132, thereby creating the indentation and curved surfaces of the tie bars 132, as described above. At this time, the adjacent package sites remain mechanically joined to one another by the dielectric material 118.

Referring to FIG. 5H, metallization processing steps are performed. These metallization processing steps form the first metallization layer 120 and the second metallization layer 126 of the semiconductor package 100 as described above. The first metallization layer 120 and the second metallization layer 126 may be formed by metal plating processes, such as electroplating and electroless plating, for example. As shown, the first metallization layer 120 may be conformally deposited so as to contact the semiconductor die 106 and the metal frame 102 and extend along the surface of the dielectric material 118. At the lower side 114 of the semiconductor package 100, the second metallization layer 126 may be patterned to form isolated bond pads. This may be done by selectively blocking the deposition of metal or by performing a subsequent etching of the deposited metal.

Referring to FIG. 5I, solder mask 128 regions are formed. The solder mask 128 regions are formed in between the lateral spaces of the first and second metallization layer 120, 126 where these layers are not present. The solder mask 128 regions may be formed by screen printing a liquid solder mask 128 material. After forming the solder mask 128, additional processing steps may be performed to finalize the semiconductor package 100. These additional processing may include cleanings steps, for example. Separately or in combination, additional processing steps may be performed to improve the surface qualities of the metallization, e.g., protection, solderability, etc. For example, an ENEPIG (Electroless Nickel Electroless Palladium Immersion Gold) process may be performed to improve solderability and reduce oxidation.

After performing the processing steps described with reference to FIGS. 5 A-5I, a package singulation step is performed to create individual semiconductor packages 100 from the first, second package and third package assemblies 200, 202, 204. The package singulation step comprises a dicing process that splits the physically connected semiconductor package 100 assemblies into individual semiconductor packages 100. This dicing process may be performed by a variety of techniques, e.g., mechanical sawing, etching, laser ablation, etc. In the case of the first and second package assemblies 200, 202, the dicing process severs both the tie bars 132 and the dielectric material 118 above the tie bars 132 thereby creating outer sides of the package with planar exposed outer contacts 130 and dielectric material 118 that is planar coplanar with the exposed outer contacts 130. In the case of the third package assembly 204, the dicing process severs the dielectric material 118 in between semiconductor package 100 sides thereby creating outer sides of the package with a planar surface of the dielectric material 118 and curved surfaces of the tie bars 132, i.e., the previously etched surfaces, that curve inward from the dielectric material 118.

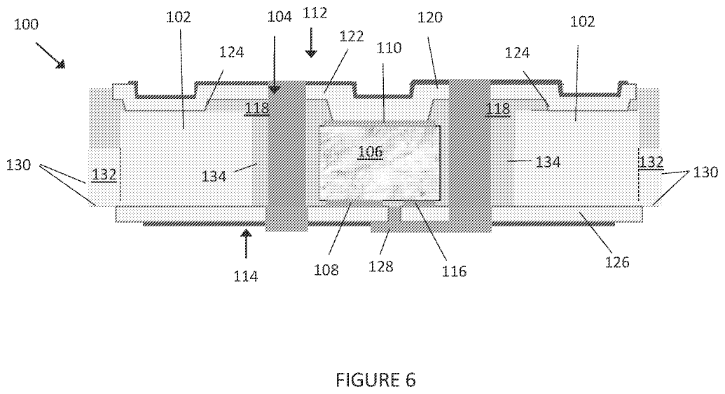

Referring to FIG. 6, a semiconductor package 100 is shown, according to an embodiment. The semiconductor package 100 is similar to that of FIG. 1, except that it comprises a metal connection 134 that extends directly between the semiconductor die 106 and the metal frame 102. This metal connection 134 is disposed below an upper surface of the metal frame 102. Thus, the metal connection 134 forms a direct metal path from the semiconductor die 106 to the metal frame 102 that is below the upper surface of the dielectric material 118. The metal connection 134 forms a thermally conductive path between the semiconductor die 106 and the metal frame 102, thus improving the heat dissipation capability of the semiconductor package 100. The metal connection 134 may also form an electrically conductive connection between the semiconductor die 106 and the metal frame 102. For example, the second terminal 110 of the semiconductor die 106 may be electrically connected with the metal connection 134, e.g., by a metallization formed at the rear surface of the semiconductor die 106 or by a sidewall connection of the semiconductor die 106. This creates a shorter distance and lower electrical resistance path than the connection provided the first metallization layer 120. Thus, the metal connection 134 may supplement or replace the connection between the second load terminal 110 and the metal frame 102 provided by the first metallization layer 120.

The metal connection 134 may be provided by placing or forming metal in between the semiconductor die 106 and the metal frame 102 before the formation of the dielectric material 118. For instance, the metal connection may be provided by plated metal regions 134 formed on the side of the semiconductor chip 106 and lead frame 102. The metal connection 134 that extends directly between the semiconductor die 106 and the metal frame 102 can be incorporated into any of the embodiments of the semiconductor package 100 disclosed herein. Optionally, the metal connection 134 may be provided in between electrical insulating structures (as shown). These electrical insulating structures may correspond to solder mask material that is used to fill holes in between the metal structures of the metal connection 134.

Although the present disclosure is not so limited, the following numbered examples demonstrate one or more aspects of the disclosure.

Example 1. A method of forming a semiconductor package, the method comprising: providing a lead frame comprising a metal frame at least partially surrounding a central opening and a plurality of tie bars connected between the metal frame and an adjacent stabilizing metal section; arranging the lead frame on a temporary carrier; arranging a semiconductor die on the temporary carrier within the central opening; forming a dielectric material that fills the central opening and encapsulates the semiconductor die; forming a first recess in the dielectric material above the semiconductor die so as to expose a first surface of the semiconductor die; electrically connecting terminals of the semiconductor die with the metal frame; and forming exposed outer contacts of the semiconductor package from the tie bars.

Example 2. The method of example 1, wherein the exposed outer contacts comprise sidewall surfaces of the tie bars.

Example 3. The method of example 2, wherein the exposed outer contacts further comprise lower surfaces of the tie bars that intersect the sidewall surfaces of the tie bars.

Example 4. The method of example 1, further comprising performing a package singulation process that severs the tie bars from the adjacent stabilizing metal section, and wherein the exposed outer contacts are provided from severed surfaces of the tie bars.

Example 5. The method of example 1, further comprising performing an etching process that removes material from the tie bars, and wherein the exposed outer contacts are provided from surfaces of the tie bars that are etched by the etching process.

Example 6. The method of example 1, wherein the semiconductor die is configured as a vertical power transistor that is configured to conduct a vertical current between a first load terminal and a second load terminal, wherein the first surface of the semiconductor die is a rear surface of the semiconductor die that comprises the second load terminal, wherein electrically connecting terminals of the semiconductor die with the metal frame comprises forming a first metallization layer at an upper side of the semiconductor package that electrically connects the second load terminal with the metal frame, and wherein the exposed outer contacts form a lead tip inspection feature that is electrically connected with the second load terminal of the semiconductor die.

Example 7. The method of example 1, wherein the lead frame is provided such that the tie bars are thinner than the metal frame, and wherein forming the dielectric material fills a region between an upper surface of the tie bars and an upper surface of the metal frame.

Example 8. The method of example 1, further comprising forming a metal connection that extends directly between the semiconductor die and the metal frame, wherein the metal connection is disposed below an upper surface of the metal frame.

Example 9. The method of example 8, wherein the metal connection electrically connects a terminal from the first surface of the semiconductor die with the metal frame.

Example 10. A semiconductor package, comprising: a metal frame that forms an at least partially enclosed shape around a central opening; severed tie bars connected with the metal frame; a semiconductor die arranged within the central opening; and a dielectric material that fills the central opening and encapsulates the semiconductor die, wherein terminals of the semiconductor die are electrically connected with the metal frame, and wherein the semiconductor package comprises exposed outer contacts of the semiconductor package formed from the severed tie bars.

Example 11. The semiconductor package of example 10, wherein the exposed outer contacts comprise sidewall surfaces of the severed tie bars.

Example 12. The semiconductor package of example 11, wherein the exposed outer contacts further comprise lower surfaces of the severed tie bars that intersect the sidewall surfaces of the severed tie bars.

Example 13. The semiconductor package of example 10, wherein a first recess is formed in the dielectric material over a first surface of the semiconductor die.

Example 14. The semiconductor package of example 13, wherein the semiconductor die is configured as a vertical power transistor that is configured to conduct a vertical current between a first load terminal and a second load terminal.

Example 15. The semiconductor package of example 14, wherein the first surface of the semiconductor die is a rear surface of the semiconductor die that comprises the second load terminal, wherein the semiconductor package comprises a first metallization layer at an upper side of the semiconductor package that electrically connects the second load terminal with the metal frame, and wherein the exposed outer contacts form a lead tip inspection feature that is electrically connected with the second load terminal of the semiconductor die.

Example 16. The semiconductor package of example 10, wherein the severed tie bars are thinner than the metal frame, and wherein the dielectric material fills a region between an upper surface of the severed tie bars and an upper surface of the metal frame.

Example 17. The semiconductor package of example 10, further comprising a metal connection that extends directly between the semiconductor die and the metal frame, wherein the metal connection is disposed below an upper surface of the metal frame.

Example 18. The semiconductor package of example 17, wherein the metal connection electrically connects a terminal from the first surface of the semiconductor die with the metal frame.

Spatially relative terms such as “under,” “below,” “lower,” “over,” “upper” and the like, are used for ease of description to explain the positioning of one element relative to a second element. These terms are intended to encompass different orientations of the device in addition to different orientations than those depicted in the figures. Further, terms such as “first,” “second,” and the like, are also used to describe various elements, regions, sections, etc. and are also not intended to be limiting. Like terms refer to like elements throughout the description.

As used herein, the terms “having,” “containing,” “including,” “comprising” and the like are open-ended terms that indicate the presence of stated elements or features, but do not preclude additional elements or features. The articles “a,” “an” and “the” are intended to include the plural as well as the singular, unless the context clearly indicates otherwise.

With the above range of variations and applications in mind, it should be understood that the present invention is not limited by the foregoing description, nor is it limited by the accompanying drawings. Instead, the present invention is limited only by the following claims and their legal equivalents.

What is claimed is:

1. A method of forming a semiconductor package, the method comprising:
providing a lead frame comprising a metal frame at least partially surrounding a central opening and a plurality of tie bars connected between the metal frame and an adjacent stabilizing metal section;
arranging the lead frame on a temporary carrier;
arranging a semiconductor die on the temporary carrier within the central opening;
forming a dielectric material that fills the central opening and encapsulates the semiconductor die;
forming a first recess in the dielectric material above the semiconductor die so as to expose a first surface of the semiconductor die;
electrically connecting terminals of the semiconductor die with the metal frame; and
forming exposed outer contacts of the semiconductor package from the tie bars.

2. The method of claim 1, wherein the exposed outer contacts comprise sidewall surfaces of the tie bars.

3. The method of claim 2, wherein the exposed outer contacts further comprise lower surfaces of the tie bars that intersect the sidewall surfaces of the tie bars.

4. The method of claim 1, further comprising performing a package singulation process that severs the tie bars from the adjacent stabilizing metal section, and wherein the exposed outer contacts are provided from severed surfaces of the tie bars.

5. The method of claim 1, further comprising performing an etching process that removes material from the tie bars, and wherein the exposed outer contacts are provided from surfaces of the tie bars that are etched by the etching process.

6. The method of claim 1, wherein the semiconductor die is configured as a vertical power transistor that is configured to conduct a vertical current between a first load terminal and a second load terminal, wherein the first surface of the semiconductor die is a rear surface of the semiconductor die that comprises the second load terminal, wherein electrically connecting terminals of the semiconductor die with the metal frame comprises forming a first metallization layer at an upper side of the semiconductor package that electrically connects the second load terminal with the metal frame, and wherein the exposed outer contacts form a lead tip inspection feature that is electrically connected with the second load terminal of the semiconductor die.

7. The method of claim 1, wherein the lead frame is provided such that the tie bars are thinner than the metal frame, and wherein forming the dielectric material fills a region between an upper surface of the tie bars and an upper surface of the metal frame.

8. The method of claim 1, further comprising forming a metal connection that extends directly between the semiconductor die and the metal frame, wherein the metal connection is disposed below an upper surface of the metal frame.

9. The method of claim 8, wherein the metal connection electrically connects a terminal from the first surface of the semiconductor die with the metal frame.

10. A semiconductor package, comprising:
a metal frame that forms an at least partially enclosed shape around a central opening;
severed tie bars connected with the metal frame;
a semiconductor die arranged within the central opening; and
a dielectric material that fills the central opening and encapsulates the semiconductor die,
wherein terminals of the semiconductor die are electrically connected with the metal frame, and
wherein the semiconductor package comprises exposed outer contacts of the semiconductor package formed from the severed tie bars.

11. The semiconductor package of claim 10, wherein the exposed outer contacts comprise sidewall surfaces of the severed tie bars.

12. The semiconductor package of claim 11, wherein the exposed outer contacts further comprise lower surfaces of the severed tie bars that intersect the sidewall surfaces of the severed tie bars.

13. The semiconductor package of claim 10, wherein a first recess is formed in the dielectric material over a first surface of the semiconductor die.

14. The semiconductor package of claim 13, wherein the semiconductor die is configured as a vertical power transistor that is configured to conduct a vertical current between a first load terminal and a second load terminal.

15. The semiconductor package of claim 14, wherein the first surface of the semiconductor die is a rear surface of the semiconductor die that comprises the second load terminal, wherein the semiconductor package comprises a first metallization layer at an upper side of the semiconductor package that electrically connects the second load terminal with the metal frame, and wherein the exposed outer contacts form a lead tip inspection feature that is electrically connected with the second load terminal of the semiconductor die.

16. The semiconductor package of claim 10, wherein the severed tie bars are thinner than the metal frame, and wherein the dielectric material fills a region between an upper surface of the severed tie bars and an upper surface of the metal frame.

17. The semiconductor package of claim 10, further comprising a metal connection that extends directly between the semiconductor die and the metal frame, wherein the metal connection is disposed below an upper surface of the metal frame.

18. The semiconductor package of claim 17, wherein the metal connection electrically connects a terminal from the first surface of the semiconductor die with the metal frame.
